(19) United States
(12) Patent Application Publication
(10) Pub. No.: US 2025/0125803 A1
(43) Pub. Date: Apr. 17, 2025

(54) Integrated Circuit Aging Tracking and Compensation

(71) Applicant: Altera Corporation, San Jose, CA (US)

(72) Inventor: Navindra Navaratnam, Portland, OR (US)

(21) Appl. No.: 18/991,041

(22) Filed: Dec. 20, 2024

(51) Int. Cl. H03K 19/003

(52) U.S. Cl. CPC H03K 19/00384

(57) ABSTRACT

Integrated circuit devices, methods, and circuitry to are provided to track and compensate for integrated circuit aging. An integrated circuit device may include first logic circuitry, a first replica of part of the first logic circuitry, a second replica of the part of the first logic circuitry, programmable voltage regulators to supply programmable voltage levels to the circuitry, and counter circuitry to measure a first oscillator count from the first replica of the part of the first logic circuitry and a second oscillator count from the second replica of the part of the first logic circuitry. A controller may control a first programmable voltage regulator to adjust a voltage level of the first logic circuitry based on the first oscillator count and the second oscillator count.

### BACKGROUND

This disclosure relates to circuitry to track integrated circuit aging to compensate for changes in behavior due to aging.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are found in numerous electronic devices and provide a variety of functionality. Over time, integrated circuits may degrade due to aging and their behavior may change. What is more, increasingly advanced integrated circuits are made using advanced process technology. Advanced integrated circuits may experience more rapid transistor aging, thus leading to reliability effects that manifest as progressive degradation of the performance of these devices. Examples of these effects include Bias Temperature Instability (BTI), Hot Carrier Injection (HCl), and Time Dependent Dielectric Breakdown (TDDB). The recent introduction of nitrogen into transistor gates may lead to worse Negative Bias Temperature Instability (NBTI) on P-channel Metal Oxide Semiconductor (PMOS) devices, resulting a positive shift in the PMOS threshold voltage attributed to hole trapping in the dielectric bulk and the breakage of silicon-hydrogen (Si—H) bonds at the dielectric interface. Aging on N-channel Metal Oxide Semiconductor (NMOS) devices has also seen an increased with the use of high-dielectric-constant (high-K) dielectric accelerating Positive Bias Temperature Instability (PBTI) effects on NMOS devices. The main BTI aging effect is propagation delay increase over time of various circuit components. If this performance degradation exceeds circuit time margins, it may lead to system failure, thus reducing its long term.

To slow the onset of these aging effects, power gating and the use of a low-frequency clock to reverse hole-trapping effects may be used. Yet while this may slow the degradation of the integrated circuit, the aging effects still do occur, albeit more slowly. To ensure that an integrated circuit still achieves its performance specifications after years of operation, integrated circuit designers may overdesign their systems. For example, an integrated circuit design may use a voltage high enough that, at the end of life of the integrated circuit, the integrated circuit still meets its performance specification. This may cause the integrated circuit to meet the performance specification at the end of life, but also may consume additional energy and cause additional integrated circuit aging over time.

### BRIEF DESCRIPTION OF THE DRAWINGS

Various aspects of this disclosure may be better understood upon reading the following detailed description and upon reference to the drawings in which:

FIG. 1 is a block diagram of a system to track and compensate for integrated circuit aging in an integrated circuit device;

FIG. 2 is a plot of voltage over time that results in the same frequency, which increases more slowly over time when aging tracking and compensation is used;

FIG. 3 is a plot of voltage over time that may be applied in a circuit design to ensure a target frequency with aging tracking and compensation and without aging tracking and compensation;

FIG. 4 is a flowchart of a method to track and compensate for integrated circuit aging;

FIG. 5 is a block diagram of circuitry to detect aging degradation using aged replica logic circuitry that has an equivalent usage to actual logic circuitry of the integrated circuit;

FIG. 6 is a block diagram of circuitry to detect aging degradation using fresh replica logic circuitry that has not been used to provide a baseline behavior to compare to the aged replica logic circuitry; and

FIG. 7 is a block diagram of a data processing system that may incorporate the system to track and compensate for integrated circuit aging.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

To mitigate the problematic effects of integrated circuit aging without overdesigning an integrated circuit design of an integrated circuit, the integrated circuit may employ a system to track and adjust a voltage of the integrated circuit design to compensate for integrated circuit aging. To this end, the integrated circuit may include the actual logic circuitry of the integrated circuit design, as well as aged replica logic circuitry and fresh replica logic circuitry. By measuring and comparing the behavior of the aged replica logic circuitry and the fresh replica logic circuitry, an amount of aging of the integrated circuit design may be determined and tracked and a voltage consumed by the integrated circuit may be adjusted to compensate. This may avoid energy losses and excess aging due to overdesigning the integrated circuit design while still achieving a performance specification throughout the lifetime of the integrated circuit.

The aged replica logic circuitry and the fresh replica logic circuitry may each replicate the same part of the actual logic circuitry. For example, the aged replica logic circuitry and the fresh replica logic circuitry may both include a replica of a critical path (e.g., a section of the actual logic circuitry that most impacts the maximum frequency that the actual logic circuitry can achieve) of the actual logic circuitry. The aged replica logic circuitry may be in operation whenever the actual logic circuitry is in use. Thus, the aged replica logic circuitry is expected to age at the same rate as the actual logic circuitry. By contrast, the fresh replica logic circuitry may be turned on only occasionally to be measured. Thus, the fresh replica logic circuitry may experience the same variation in behavior due to environmental effects (e.g., temperature, location, altitude) as the aged replica logic circuitry but may not experience aging due to operation. This allows the fresh replica logic circuitry to serve as a baseline in relation to the aged replica logic circuitry. A controller may use the difference between the fresh replica logic circuitry and the aged replica logic circuitry may to determine an appropriate voltage to supply to the actual logic circuitry. The controller may select a voltage that ensures proper operation of the actual logic circuitry. Especially during operation early in the lifetime of the integrated circuit, this voltage may be significantly lower than an overdesigned voltage selected to ensure operation at the end of the lifetime of the integrated circuit.

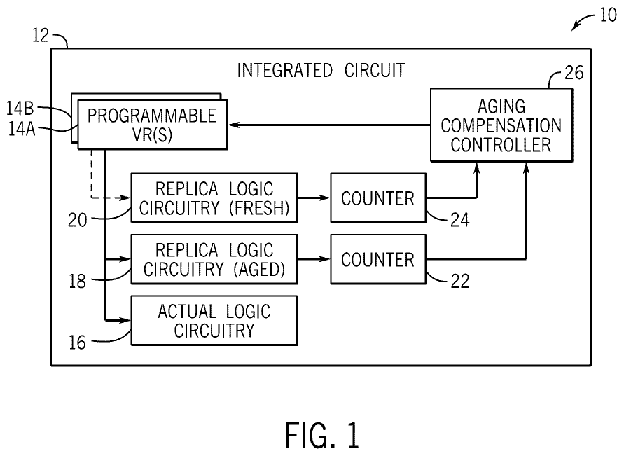

FIG. 1 illustrates a system 10 to track and compensate for aging in an integrated circuit device 12. The integrated circuit device 12 may include any suitable integrated circuit(s). For example, the integrated circuit device 12 may include a programmable logic device (PLD), such as a field programmable gate array (FPGA), or may be an application specific integrated circuit (ASIC). Additionally or alternatively, the integrated circuit device 12 may include a processor (e.g., central processing unit (CPU), graphics processing unit (GPU)), artificial intelligence (AI) compute circuitry, memory or storage (e.g., random access memory (RAM), read only memory (ROM), nonvolatile memory, high-bandwidth memory (HBM)), or the like.

The integrated circuit device 12 may include a number of programmable voltage regulators (VRs) 14A, 14B that may be digitally programmed to provide a particular voltage level. In the example of FIG. 1, the programmable VR 14A supplies voltage to actual logic circuitry 16 and aged replica logic circuitry 18. The programmable VR 14B supplies voltage to fresh replica logic circuitry 20. The actual logic circuitry 16 may represent any data utilization circuitry that performs a data processing function. The aged replica logic circuitry 18 and the fresh replica logic circuitry 20 may both include a replica of part of the actual logic circuitry 16 (e.g., a critical path, which is a section of the actual logic circuitry 16 that most impacts the maximum frequency that the actual logic circuitry 16 can achieve). The aged replica logic circuitry 18 may receive a voltage from the programmable VR 14A and may operate whenever the actual logic circuitry is in use. Thus, the aged replica logic circuitry 18 is expected to age at the same rate as the actual logic circuitry 16. By contrast, the programmable VR 14B may supply a voltage to the fresh replica logic circuitry 20 only rarely to be measured—most of the time, the voltage supply to the fresh replica logic circuitry 20 may be power gated (e.g., driven to ground, driven to 0V). Thus, while the fresh replica logic circuitry 20 may experience the same variation in behavior due to environmental effects (e.g., temperature, location, altitude) as the aged replica logic circuitry 18, the fresh replica logic circuitry 20 may not experience aging due to operation.

Counters 22 and 24 may occasionally measure the behavior of the aged replica logic circuitry 18 and the fresh replica logic circuitry 20, respectively. After operating for an extended period of time (e.g., weeks, months, years), the circuitry of the integrated circuit device 12 may operate more slowly at a particular voltage level. The counter 22 may provide an oscillator count from the aged replica logic circuitry 18 and the counter 24 may provide an oscillator count from the fresh replica logic circuitry 20. Due to aging, over time, the counts may diverge as the aged replica logic circuitry 18 (and, by extension, the actual logic circuitry 16) runs more slowly than the fresh replica logic circuitry 20.

An aging compensation controller 26 may treat the counts from the counter 24 as a baseline by which to compare the counts from the counter 22. The aging compensation controller 26 may determine a difference between the counts from the counter 24 and the counts from the counter 22. This may be in absolute terms (e.g., difference in total counts) or in relative terms (e.g., difference in rate of counts). Based on the difference, the aging compensation controller 26 may program the programmable VR 14A to supply a voltage to the actual logic circuitry 16 (and the aged replica logic circuitry 18) that compensates for the difference in counts. For example, the voltage programmed by the aging compensation controller 26 may be selected to cause the counts from the counter 22 to be equal to or greater than the counts from the counter 24. The aging compensation controller 26 may increment the voltage output by the programmable VR 14A until the counts from the counter 22 are equal to or greater by some threshold than the counts from the counter 24. The aging compensation controller 26 may take any suitable form. For example, the aging compensation controller 26 may include a finite state machine (FSM) or a microcontroller that executes firmware loaded from tangible, non-transitory, machine-readable media on or outside of the integrated circuit device 12.

The integrated circuit device 12 may include any suitable number of regions that include the circuitry shown in FIG. 1. Indeed, the circuitry shown in FIG. 1 may be repeated in various locations throughout the integrated circuit device 12. There may be many different areas of actual logic circuitry with different patterns of operation that may result in different degrees of aging. Therefore, it may be beneficial to track and adjust the voltage supplied to other actual logic circuitry, as well. For example, the integrated circuit device 12 may include first actual logic circuitry that operates substantially all of the time and second actual logic circuitry that operates only part of the time (e.g., may have a lower duty cycle, may be power gated part of the time that the first actual logic circuitry is operating). These other regions of actual logic circuitry may be supplied with different voltages from different programmable VRs and may be tested using their own corresponding aged and fresh logic replica circuitry.

In one specific example, the integrated circuit device 12 may include programmable logic circuitry (e.g., FPGA circuitry such as found in the Agilex™, Stratix®, Arria®, MAX®, or Cyclone® devices by Altera®) that can be programmed with a circuit design in the actual logic circuitry 16, the aged logic circuitry 18, and the fresh logic circuitry 20. At a later time, the aged region of the actual logic circuitry 16 and the aged logic circuitry 18 may be reprogrammed (e.g., partially reconfigured) with a new circuit design in these regions that have experienced integrated circuit aging due to the operation of the previous design. The fresh replica logic circuitry 20 may be reprogrammed (e.g., partially reconfigured) with the new replica logic circuitry 20 corresponding to the aged logic circuitry 18 and, since the fresh replica logic circuitry 20 was previously not operated except for occasional measurements, the fresh replica logic circuitry 20 may still effectively serve the function of representing non-aged circuitry to serve as a baseline for the new aged replica logic circuitry 18.

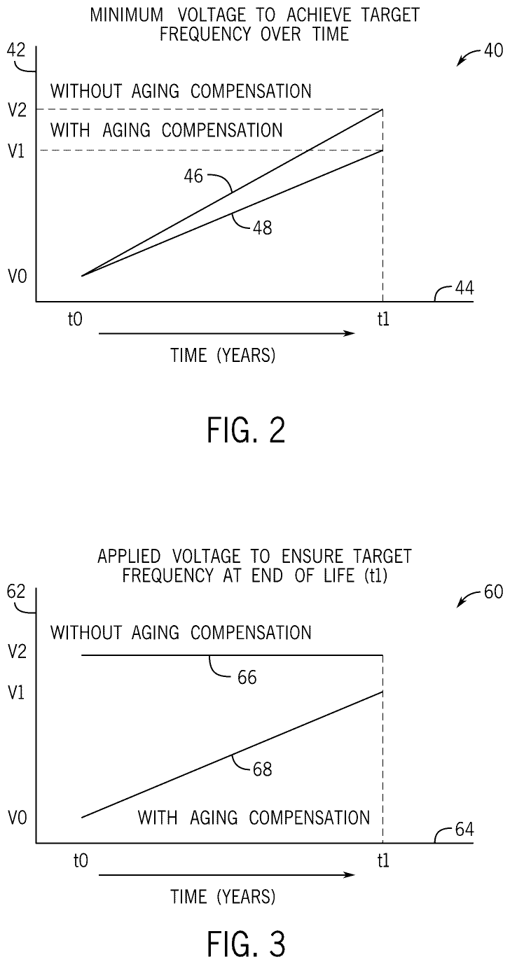

Tracking and compensating for integrated circuit aging may not only reduce the total amount of power consumed by the integrated circuit device 12, but also may reduce overall integrated circuit aging. FIG. 2 provides an example of a plot 40 of the minimum voltage used to achieve some target operating frequency for actual logic circuitry of an integrated circuit device over the lifetime of the device. An ordinate 42 represents voltage levels (shown as V0, V1, and V2) and an abscissa 44 represents time in years from a beginning of life (t0) to an end of life (t1) of the integrated circuit device. Due to integrated circuit device aging, maintaining the same target frequency of operation involves a higher and higher voltage as time goes by. The voltage level increases at a higher rate, as shown by a line 46, without the aging compensation of this disclosure. The voltage level still increases, but at a lower rate, as shown by a line 48, when the aging compensation of this disclosure is used.

This is because, as shown by a plot 60 in FIG. 3, without aging compensation the maximum voltage level is applied for the duration of the life of the integrated circuit device. An ordinate 62 represents the same voltage levels as in the plot 40 (shown as V0, V1, and V2) and an abscissa 64 represents the same time in years from the beginning of life (t0) to the end of life (t1) of the integrated circuit device. Without aging compensation, a circuit designer may ensure that the target frequency of operation is still achieved at the end of life (t1) by selecting that voltage level to operate at all times, as shown by a line 66. By contrast, as shown by a line 68, the voltage level may be adaptively increased based on the amount of aging that is detected over time when the aging compensation of this disclosure is used. As can be seen, not only does the aging compensation of this disclosure reduce the total amount of energy consumed over the life of the integrated circuit device, but it also reduces the total amount of integrated circuit aging. This is because the greater the voltage applied to the integrated circuit, the greater the integrated circuit aging.

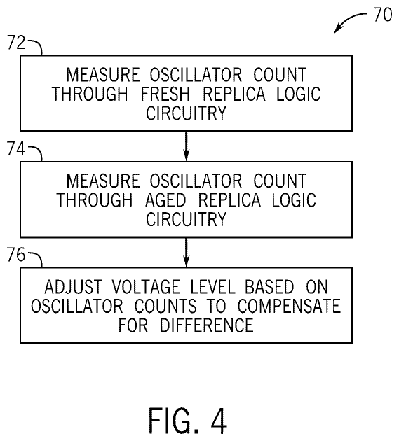

FIG. 4 is a flowchart 70 of a method for performing aging compensation using the circuitry shown in FIG. 1. The method of the flowchart 70 may be performed periodically or on demand. For example, the aging compensation controller 26 may initiate or may be prompted to initiate the method of the flowchart 70. At the start of the flowchart 70, the aging compensation controller 26 may simultaneously obtain a measurement of an oscillator count through the fresh replica logic circuitry 20 (block 72) and a measurement of an oscillator count through the aged replica logic circuitry 18 (block 74). For example, the programmable VR 14B may be programmed with a defined voltage of the integrated circuit to provide a desired target frequency (e.g., the defined voltage may be VO, which results in the target frequency at the start of life (t1) in the plots 40 and 60 of FIGS. 2 and 3). The voltage supplied to the fresh replica logic circuitry 20 may be un-gated to provide power to the fresh replica logic circuitry 20 to enable measurement. The counter 24 may measure any suitable defined number of oscillator counts through the fresh replica logic circuitry 20. Meanwhile, the programmable VR 14A may remain programmed with a voltage level based on the previous time that aging compensation was applied. The counter 22 may simultaneously measure the number of oscillator counts through the aged replica logic circuitry 18 over the amount of time it takes for the counter 24 to measure the defined number of oscillator counts through the fresh replica logic circuitry 20. For example, the counter 22 may be disabled as soon as the counter 24 counts the defined number of oscillator counts. Additionally or alternatively, the counters 22 and 24 may operate for a defined equal number of clock cycles based on a common clock signal.

The aging compensation controller 26 may adjust the voltage level of the programmable VR 14A to compensate for a difference between the oscillator counts from the counters 22 and 24 (block 76). In one example, the aging compensation controller 26 may gradually increment or decrement a voltage control signal (e.g., a digital or analog control signal) by some amount and then perform the method of the flowchart 70 again. This may continue until the oscillator counts from the counters 22 and 24 substantially match or the oscillator counts from the counter 22 exceeds the oscillator counts from the counter 24 by a threshold amount (e.g., a guardband). Additionally or alternatively, the aging compensation controller 26 may apply a function (e.g., perform a calculation, index a lookup table storing a function) to obtain a voltage adjustment based on the difference between the oscillator counts from the counters 22 and 24.

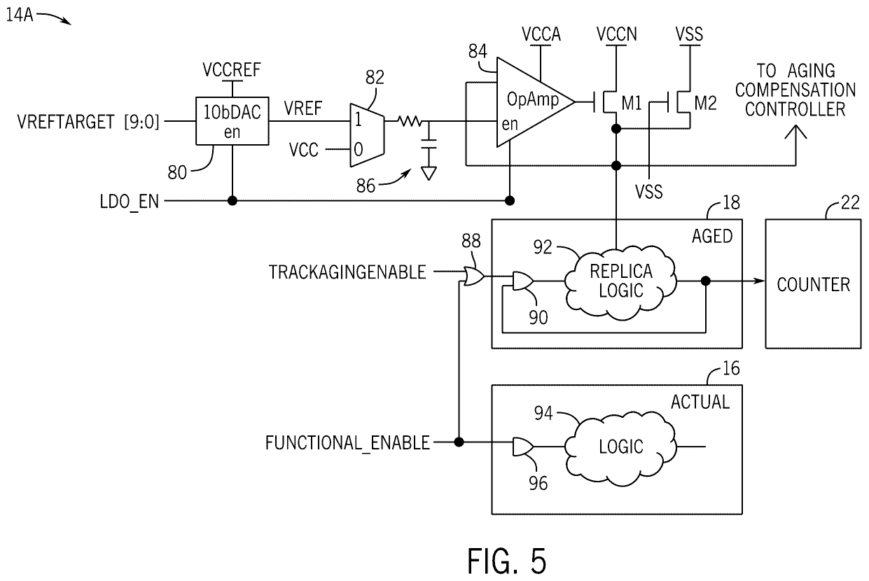

FIG. 5 provides a circuit diagram of the programmable VR 14A that supplies a voltage to the actual logic circuitry 16 and the aged replica logic circuitry 18. In the example of FIG. 5, a 10-bit digital reference target voltage signal (VrefTarget [9:0]) (e.g., provided by the aging compensation controller 26) may be used by a 10-bit digital to analog converter (DAC) 80 to generate a reference voltage signal (Vref) based on a reference supply voltage (VccRef) when enabled by an amplifier enable signal (LDO_En). Although the DAC 80 is described as a 10-bit DAC, the DAC 80 may have any suitable bit width, which may be higher or lower (e.g., 4-bit, 5-bit, 6-bit, 7-bit, 8-bit, 9-bit, 11-bit, 12-bit, and so forth). A multiplexer 82 may enable the selection of either the programmable reference voltage signal (Vref) or a global supply reference voltage signal (Vcc) as reference into an operational amplifier (OpAmp) 84. The selected voltage signal from the multiplexer 82 may be conditioned by any suitable filtering circuitry 86 to prevent rapid changes. The OpAmp 84 may receive an amplifier supply voltage (vcca) and may also be enabled by the amplifier enable signal (LDO_En). The OpAmp 84 generates a signal that is applied to a gate of a transistor M1, which is connected between a circuitry supply rail voltage (vccn). The output voltage of the transistor M1, which is supplied to the actual logic circuitry 16 and the aged replica logic circuitry 18, varies based on the signal applied to the gate of the transistor M1. Due to feedback into the OpAmp, the output voltage of the transistor M1 is equal to the reference voltage (Vref) output by the DAC 80. Note that another transistor M2 may be used for power gating purposes, but is not in use in the circuitry of FIG. 5. Both the drain and the gate of the transistor M2 are tied to the same voltage level, so the transistor M2 remains open and therefore does not power gate the circuitry in FIG. 5.

The actual logic circuitry 16 and the aged replica logic circuitry 18 may be selectively enabled by a Functional_Enable signal. The Functional_Enable signal activates both the actual logic circuitry 16 and the aged replica logic circuitry 18 so that the aged replica logic circuitry 18 is operational (and aging) whenever the actual logic circuitry 16 is operational. In addition, the aged replica logic circuitry 18 may be selectively (but briefly) activated by a TrackingAgingEnable signal even when the actual logic circuitry 16 is not in use. This is to allow the aged replica logic circuitry 18 to be measured even when the actual logic circuitry 16 is not operating (e.g., to determine the reference voltage Vref for the actual logic circuitry 16 before the actual logic circuitry 16 is activated). To this end, the TrackingAgingEnable signal and the Functional_Enable signal may enter an OR gate 88 that feeds into the aged replica logic circuitry 18.

The aged replica logic circuitry 18 may be arranged in a ring oscillator configuration, as shown in FIG. 5. Thus, an AND gate 90 may be connected to the output of combinatorial logic 92 representing a replica of some part of combinatorial logic 94 from the actual logic circuitry 16. The output of the OR gate 88 also feeds into the AND gate 90. The oscillations output by the combinatorial logic 92 of the aged replica logic circuitry 18 may be counted by the counter 22. The actual logic circuitry 16 may also include an AND gate 96. Additionally or alternatively, the actual logic circuitry 16 may be selectively operated in a ring oscillator configuration with the AND gate 96 in addition to, or instead of, using the aged replica logic circuitry 18. Thus, if desired, the actual logic circuitry 16 may be directly measured (e.g., by the counter 22) instead of the aged replica logic circuitry 18 (e.g., in this example, the aged replica logic circuitry 18 may not be present). This may only be feasible, however, when the actual logic circuitry 16 is not in use. Therefore, this may be done to the extent that the actual logic circuitry 16 is expected not to be in constant use.

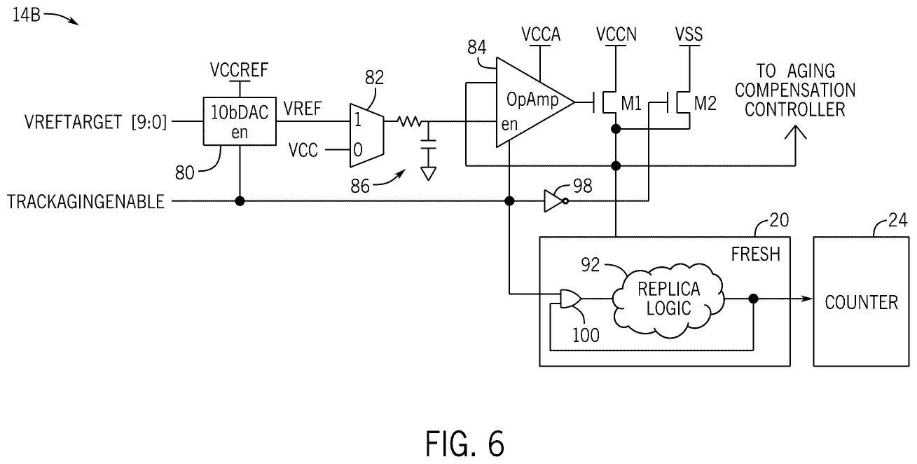

FIG. 6 provides a circuit diagram of the programmable VR 14B that supplies a voltage to the fresh replica logic circuitry 20. In the example of FIG. 6, elements with like element numbers may be understood to be comparable to those described above with reference to FIG. 5. In the example of FIG. 6, however, the DAC 80 and the OpAmp 84 are enabled not by the amplifier enable signal (LDO_En) but rather by the TrackingAgingEnable signal. In addition, an inverter 98 outputs an inverted TrackingAgingEnable signal to the gate of the M2 transistor. As such, when the TrackingAgingEnable signal is not enabling the DAC 80, the OpAmp 84, and the fresh replica logic circuitry 20, the transistor M2 is power gating the fresh replica logic circuitry 20 so that the fresh replica logic circuitry 20 remains grounded unless it is being measured. This eliminates aging effects on the fresh replica logic circuitry 20 when the fresh replica logic circuitry 20 not being measured. When the TrackingAgingEnable signal is enabling the DAC 80, the OpAmp 84, and the fresh replica logic circuitry 20, the transistor M2 allows power to flow to the fresh replica logic circuitry 20. The fresh replica logic circuitry 20 may also be arranged in a ring oscillator configuration with the same combinatorial logic 92 as used by the aged replica logic circuitry 18 using an AND gate 100. The oscillations output by the combinatorial logic 92 of the fresh replica logic circuitry 20 may be counted by the counter 24.

Before beginning any measurements, the aging compensation controller 26 may calibrate the programmable VRs 14A and 14B. To calibrate the programmable VRs 14A and 14B, the programmable VRs 14A and 14B may be programmed with the same Vref or one or both of the multiplexers 82 may be set to provide Vcc. The aging compensation controller 26 may compare the resulting outputs of the transistor M1 of the programmable VR 14A and the transistor M1 of the programmable VR 14B. The aging compensation controller 26 may set an offset compensation to one of the programmable VRs 14A and 14B so that, for a given target voltage, both of the programmable VRs 14A and 14B will output the same value. The offset compensation may be implemented as a change to the reference target voltage signal (VrefTarget), a change to the behavior of the DAC 80 (e.g., adjusting tap location or voltages), and/or a change to the supply voltage to the OpAmp 84 of one or both of the programmable VRs 14A or 14B. This calibration may take place before every measurement or once at the beginning of life (BOL) of the integrated circuit device 12.

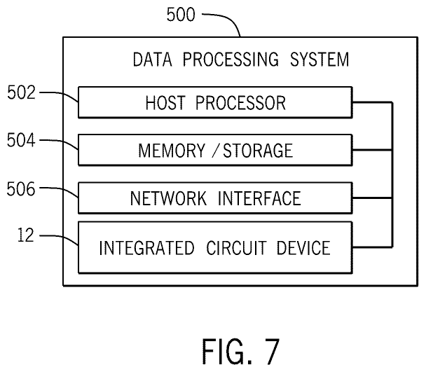

The aging tracking and compensation system 10 may be included in any suitable integrated circuit devices of a data processing system, such as a data processing system 500, shown in FIG. 7. The data processing system 500 may include the integrated circuit device 12 of this disclosure, a host processor 502, memory and/or storage circuitry 504, and a network interface 506. The data processing system 500 may include more or fewer components (e.g., electronic display, user interface structures, application specific integrated circuits (ASICs)). Moreover, any of the circuit components depicted in FIG. 7 may include various aspects of the aging tracking and compensation system of this disclosure. The host processor 502 may include any of suitable processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like).

The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit device 12 when it includes programmable logic circuitry (e.g., FPGA circuitry). The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. For example, the aging tracking and compensation system of this disclosure may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

### EXAMPLE EMBODIMENTS

EXAMPLE EMBODIMENT 1. An integrated circuit device comprising:
first logic circuitry;
a first replica of part of the first logic circuitry;
a second replica of the part of the first logic circuitry;

a first programmable voltage regulator to supply a first programmable voltage to the first logic circuitry and the first replica of part of the first logic circuitry;

a second programmable voltage regulator to supply a second programmable voltage to the second replica of the part of the first logic circuitry;

counter circuitry to measure a first oscillator count from the first replica of the part of the first logic circuitry and a second oscillator count from the second replica of the part of the first logic circuitry; and

a controller to control the first programmable voltage regulator to adjust the first programmable voltage based on the first oscillator count and the second oscillator count.

EXAMPLE EMBODIMENT 2. The integrated circuit device of example embodiment 1, wherein the part of the first logic circuitry that is replicated is a critical path of the first logic circuitry.

EXAMPLE EMBODIMENT 3. The integrated circuit device of example embodiment 1, wherein the first programmable voltage regulator is to supply the first programmable voltage to the first replica of the part of the first logic circuitry at least while the first logic circuitry is operational to cause the first replica of the part of the first logic circuitry to age at the same rate as the first logic circuitry.

EXAMPLE EMBODIMENT 4. The integrated circuit device of example embodiment 3, wherein the second programmable voltage regulator is configured to power gate the second programmable voltage from the second replica of the part of the first logic circuitry when the counter circuitry is not used to measure the first oscillator count from the first replica of the part of the first logic circuitry and the second oscillator count from the second replica of the part of the first logic circuitry.

EXAMPLE EMBODIMENT 5. The integrated circuit device of example embodiment 1, wherein the counter circuitry is configured to measure the first oscillator count from the first replica of the part of the first logic circuitry until the second oscillator count from the second replica of the part of the first logic circuitry reaches a defined value.

EXAMPLE EMBODIMENT 6. The integrated circuit device of example embodiment 1, wherein the counter circuitry is configured to measure the first oscillator count from the first replica of the part of the first logic circuitry and the second oscillator count from the second replica of the part of the first logic circuitry for a defined number of clock cycles.

EXAMPLE EMBODIMENT 7. The integrated circuit device of example embodiment 1, wherein the controller comprises a finite state machine.

EXAMPLE EMBODIMENT 8. The integrated circuit device of example embodiment 1, wherein the controller comprises a microcontroller.

EXAMPLE EMBODIMENT 9. The integrated circuit device of example embodiment 1, wherein the controller is configured to control the first programmable voltage regulator to adjust the first programmable voltage based on a difference between the first oscillator count and the second oscillator count.

EXAMPLE EMBODIMENT 10. The integrated circuit device of example embodiment 9, wherein the controller is configured to control the first programmable voltage regulator to adjust the first programmable voltage to cause the first oscillator count or a rate of the first oscillator count to match or exceed the second oscillator count of a rate of the second oscillator count.

EXAMPLE EMBODIMENT 11. The integrated circuit device of example embodiment 1, wherein the controller is configured to issue a digital control signal to the first programmable voltage regulator to control the first programmable voltage regulator, wherein the digital control signal causes the first programmable voltage regulator to adjust the first programmable voltage.

EXAMPLE EMBODIMENT 12. The integrated circuit device of example embodiment 11, wherein the controller is configured to increment or decrement the digital control signal based on a difference between the first oscillator count and the second oscillator count.

EXAMPLE EMBODIMENT 13. A method comprising:

measuring a first oscillator count through aged replica logic circuitry comprising a first replica of a portion of actual logic circuitry, wherein the aged replica logic circuitry has been activated over a lifetime of operation of the actual logic circuitry;

measuring a second oscillator count through fresh replica logic circuitry comprising a second replica of the portion of the actual logic circuitry, wherein the fresh replica logic circuitry has not been activated over the lifetime of operation of the actual logic circuitry; and

adjusting a voltage level of the actual logic circuitry based on the first oscillator count and the second oscillator count.

EXAMPLE EMBODIMENT 14. The method of example embodiment 13, wherein the fresh replica logic circuitry is configured to be power gated except while being measured.

EXAMPLE EMBODIMENT 15. The method of example embodiment 13, wherein the voltage level is adjusted based on a difference between the first oscillator count and the second oscillator count.

EXAMPLE EMBODIMENT 16. The method of example embodiment 13, wherein the voltage level is adjusted higher over time to account for aging of the actual logic circuitry indicated by a change in the first oscillator count relative to the second oscillator count over time.

EXAMPLE EMBODIMENT 17. The method of example embodiment 13, comprising repeating the recited acts until the first oscillator count or a rate of the first oscillator count is equal to or greater than the second oscillator count or a rate of the second oscillator count.

EXAMPLE EMBODIMENT 18. Circuitry comprising:

first logic circuitry to perform a data processing operation;

aged replica logic circuitry comprising a first replica of a segment of the first logic circuitry that is configured to be in operation substantially while the first logic circuitry is operating;

fresh replica logic circuitry comprising a second replica of the segment of the first logic circuitry that is configured to be in operation for less time than aged replica logic circuitry; and

a controller configured to adjust a voltage level of the first logic circuitry to compensate for aging of the actual logic circuitry based on a difference in behavior between the aged replica logic circuitry and the fresh replica logic circuitry.

EXAMPLE EMBODIMENT 19. The circuitry of example embodiment 18, wherein the difference in behavior between the aged replica logic circuitry and the fresh replica logic circuitry comprises a difference in oscillator counts.

EXAMPLE EMBODIMENT 20. The circuitry of example embodiment 18, comprising an OR logic gate configured to activate the aged replica logic circuitry based on receiving a first enable signal that also enables operation of the first logic circuitry or a second enable signal to enable measurement of the behavior of the aged replica logic circuitry.

What is claimed is:

1. An integrated circuit device comprising:
first logic circuitry;
a first replica of part of the first logic circuitry;
a second replica of the part of the first logic circuitry;
a first programmable voltage regulator to supply a first programmable voltage to the first logic circuitry and the first replica of part of the first logic circuitry;
a second programmable voltage regulator to supply a second programmable voltage to the second replica of the part of the first logic circuitry;
counter circuitry to measure a first oscillator count from the first replica of the part of the first logic circuitry and a second oscillator count from the second replica of the part of the first logic circuitry; and
a controller to control the first programmable voltage regulator to adjust the first programmable voltage based on the first oscillator count and the second oscillator count.

2. The integrated circuit device of claim 1, wherein the part of the first logic circuitry that is replicated is a critical path of the first logic circuitry.

3. The integrated circuit device of claim 1, wherein the first programmable voltage regulator is to supply the first programmable voltage to the first replica of the part of the first logic circuitry at least while the first logic circuitry is operational to cause the first replica of the part of the first logic circuitry to age at the same rate as the first logic circuitry.

4. The integrated circuit device of claim 3, wherein the second programmable voltage regulator is configured to power gate the second programmable voltage from the second replica of the part of the first logic circuitry when the counter circuitry is not used to measure the first oscillator count from the first replica of the part of the first logic circuitry and the second oscillator count from the second replica of the part of the first logic circuitry.

5. The integrated circuit device of claim 1, wherein the counter circuitry is configured to measure the first oscillator count from the first replica of the part of the first logic circuitry until the second oscillator count from the second replica of the part of the first logic circuitry reaches a defined value.

6. The integrated circuit device of claim 1, wherein the counter circuitry is configured to measure the first oscillator count from the first replica of the part of the first logic circuitry and the second oscillator count from the second replica of the part of the first logic circuitry for a defined number of clock cycles.

7. The integrated circuit device of claim 1, wherein the controller comprises a finite state machine.

8. The integrated circuit device of claim 1, wherein the controller comprises a microcontroller.

9. The integrated circuit device of claim 1, wherein the controller is configured to control the first programmable voltage regulator to adjust the first programmable voltage based on a difference between the first oscillator count and the second oscillator count.

10. The integrated circuit device of claim 9, wherein the controller is configured to control the first programmable voltage regulator to adjust the first programmable voltage to cause the first oscillator count or a rate of the first oscillator count to match or exceed the second oscillator count of a rate of the second oscillator count.

11. The integrated circuit device of claim 1, wherein the controller is configured to issue a digital control signal to the first programmable voltage regulator to control the first programmable voltage regulator, wherein the digital control signal causes the first programmable voltage regulator to adjust the first programmable voltage.

12. The integrated circuit device of claim 11, wherein the controller is configured to increment or decrement the digital control signal based on a difference between the first oscillator count and the second oscillator count.

13. A method comprising:
measuring a first oscillator count through aged replica logic circuitry comprising a first replica of a portion of actual logic circuitry, wherein the aged replica logic circuitry has been activated over a lifetime of operation of the actual logic circuitry;
measuring a second oscillator count through fresh replica logic circuitry comprising a second replica of the portion of the actual logic circuitry, wherein the fresh replica logic circuitry has not been activated over the lifetime of operation of the actual logic circuitry; and
adjusting a voltage level of the actual logic circuitry based on the first oscillator count and the second oscillator count.

14. The method of claim 13, wherein the fresh replica logic circuitry is configured to be power gated except while being measured.

15. The method of claim 13, wherein the voltage level is adjusted based on a difference between the first oscillator count and the second oscillator count.

16. The method of claim 13, wherein the voltage level is adjusted higher over time to account for aging of the actual logic circuitry indicated by a change in the first oscillator count relative to the second oscillator count over time.

17. The method of claim 13, comprising repeating the recited acts until the first oscillator count or a rate of the first oscillator count is equal to or greater than the second oscillator count or a rate of the second oscillator count.

18. Circuitry comprising:
first logic circuitry to perform a data processing operation;
aged replica logic circuitry comprising a first replica of a segment of the first logic circuitry that is configured to be in operation substantially while the first logic circuitry is operating;
fresh replica logic circuitry comprising a second replica of the segment of the first logic circuitry that is configured to be in operation for less time than aged replica logic circuitry; and
a controller configured to adjust a voltage level of the first logic circuitry to compensate for aging of the actual logic circuitry based on a difference in behavior between the aged replica logic circuitry and the fresh replica logic circuitry.

19. The circuitry of claim 18, wherein the difference in behavior between the aged replica logic circuitry and the fresh replica logic circuitry comprises a difference in oscillator counts.

20. The circuitry of claim 18, comprising an OR logic gate configured to activate the aged replica logic circuitry based on receiving a first enable signal that also enables operation of the first logic circuitry or a second enable signal to enable measurement of the behavior of the aged replica logic circuitry.
